(19) United States
(12) Patent Application Publication
(10) Pub. No.: US 2004/0022884 A1
(43) Pub. Date: Feb. 5, 2004

(54) Resin molding apparatus

(75) Inventor: Itaru Matsuo, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/431,376

(22) Filed: May 8, 2003

(30) Foreign Application Priority Data
Jul. 30, 2002 (JP) 2002-220964

(51) Int. Cl. B29C 45/14; H01L 21/56

(52) U.S. Cl. 425/116; 425/126.1; 425/129.1; 425/544; 425/DIG. 228

(57) ABSTRACT

A resin molding apparatus including a holder for controllably holding and releasing a lead frame having a first and second principal surfaces and a plurality of elements mounted on at least one of the first and second principal surfaces. The resin molding apparatus also includes a transporter for transporting the holder with the lead frame from a first position via a second position to a third position. Further it has a first and second molding dice controllably adjoining the first and second principal surfaces of the lead frame arranged on the second position, respectively, so that a molding cavity is defined therebetween, which covers the element of the lead frame. A resin injector is provided for injecting resin into the molding cavity; and also an elevator is arranged on the second position for elevating the holder with the lead frame in a direction perpendicular to the first and second principal surfaces.

### BACKGROUND OF THE INVENTION

1) Technical Field of the Invention

The present invention relates to a resin molding apparatus for molding one or more elements mounted on a lead frame with resin.

2) Description of Related Arts

A variety of the resin molding apparatuses have been proposed, in which a plurality of elements such as semiconductor devices mounted on the lead frame are covered and molded (sealed) with resin, at one time. Therefore, those resin molding apparatuses have an advantage of a high productivity, but several drawbacks on the other hand. For example, the resin molding apparatus requires a substantially large space (area) in the facility for the installation. Also, the apparatus and a pair of molding dice used therein are relatively expensive. A substantial percentage of source resin are not used for actual molded products and are wasted to form the cured resin within a cull and runner portions, i.e., the material-product efficiency is poor. Further, the undue power consumption is required to move the molding dice with a substantial weight relative to the lead frame, i.e., the energy efficiency is limited. In addition, according to the conventional resin molding apparatus, the large area of the molding dice causes a pressure variation between the contacting surfaces of the dice and the lead frame, and a temperature variation of injected resin both varying based upon the positions within the die.

Further, the conventional resin molding apparatus needs another mechanism (step) for removing the cured resin within the cull and runner portions connecting with the lead frame.

Also, the conventional resin molding apparatus needs the expensive molding dice, which includes a separating mechanism within the molding dice for separating the lead frame molded by injecting the resin from the molding dice.

### SUMMARY OF THE INVENTION

Further scope of applicability of the present invention will become apparent from the detailed description given hereinafter. However, it should be understood that the detailed description and specific examples, while indicating preferred embodiments of the invention, are given by way of illustration only, since various changes and modifications within the sprit and scope of the invention will become apparent to those skilled in the art from this detailed description.

One of the aspects of the present invention is to provide a resin molding apparatus including a holder for controllably holding and releasing a lead frame having a first and second principal surfaces and a plurality of elements mounted on at least one of the first and second principal surfaces. The resin molding apparatus also includes a transporter for transporting the holder with the lead frame from a first position via a second position to a third position. Further it has a first and second molding dice controllably adjoining the first and second principal surfaces of the lead frame arranged on the second position, respectively, so that a molding cavity is defined therebetween, which covers the element of the lead frame. A resin injector is provided for injecting resin into the molding cavity; and also an elevator is arranged on the second position for elevating the holder with the lead frame in a direction perpendicular to the first and second principal surfaces.

Further scope of applicability of the present invention will become apparent from the detailed description given hereinafter. However it should be understood that the detailed description and specific examples, while indicating preferred embodiments of the invention, are given by way of illustration only, since various changes and modifications within the sprit and scope of the invention will become apparent to those skilled in the art from this detailed description.

### BRIEF DESCRIPTION OF THE DRAWINGS

The present invention will more fully be understood from the detailed description given hereinafter and accompanying drawings which are given by way of illustration only, and thus are not limitative of the present invention and wherein,

FIG. 1 is a perspective view of the resin molding apparatus according to the present invention;

FIG. 2 is a partial perspective view of the resin molding apparatus of FIG. 1;

FIG. 3 is a partial cross sectional view, taken along the Y-Z plane of FIG. 1, of the resin molding apparatus;

FIGS. 4A to 4D are partial cross sectional views, taken along the X-Z plane of FIG. 1, and FIG. 4E is a cross sectional view, taken along the Y-Z plane of FIG. 1 of the resin tablet loading mechanism according to the present invention;

FIGS. 5A to 5C are elevation views of the resin tablet loading mechanism according to the present invention;

FIGS. 6A and 6B are partial cross sectional views, taken along the X-Z plane of FIG. 1, and FIG. 6C is a cross sectional view, taken along the Y-Z plane of FIG. 1, of the resin injecting mechanism according to the first embodiment; and

FIGS. 7A and 7B are partial cross sectional views, taken along the X-Z plane of FIG. 1, of the resin injecting mechanism according to the second embodiment.

### DETAILED DESCRIPTION OF THE PREFERRED EMBODIMENTS

Referring to the attached drawings, the details of embodiments according to the present invention will be described hereinafter. In those descriptions and drawings, although the terminology indicating the directions (for example, “upper”, “lower”, “top”, “bottom”, “X-direction”, “Y-direction” and “Z-direction”) are conveniently used just for clear understandings, it should not be interpreted that those terminology limit the scope of the present invention.

Embodiment 1.

The resin molding apparatus includes several components having some sub-components. Firstly the detailed structure of such components will be described, and the operation how the resin molding apparatus works will be discussed later.

I. Structure of Resin Molding Apparatus

(1) Platform

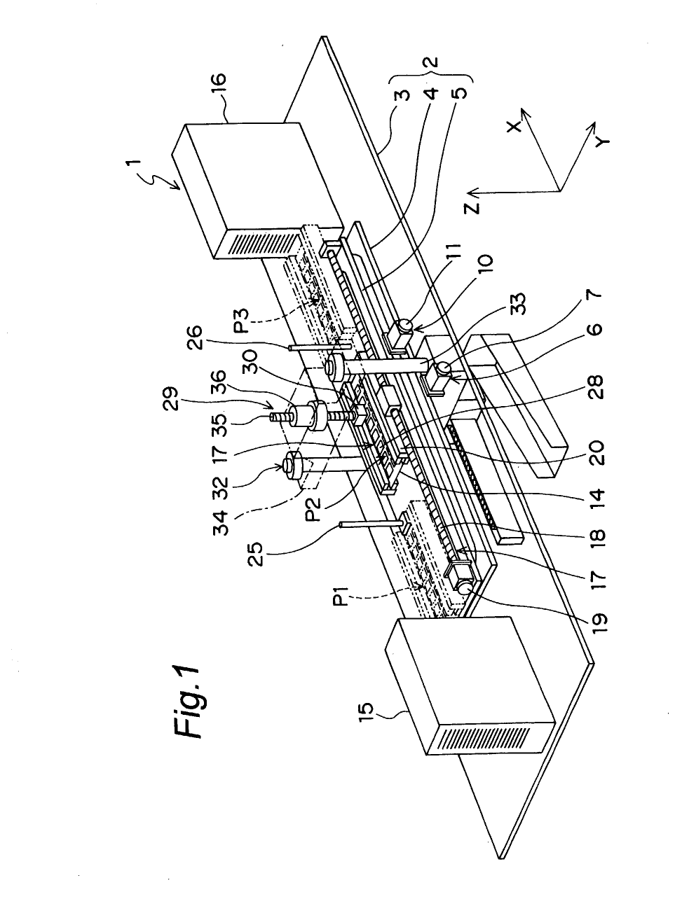

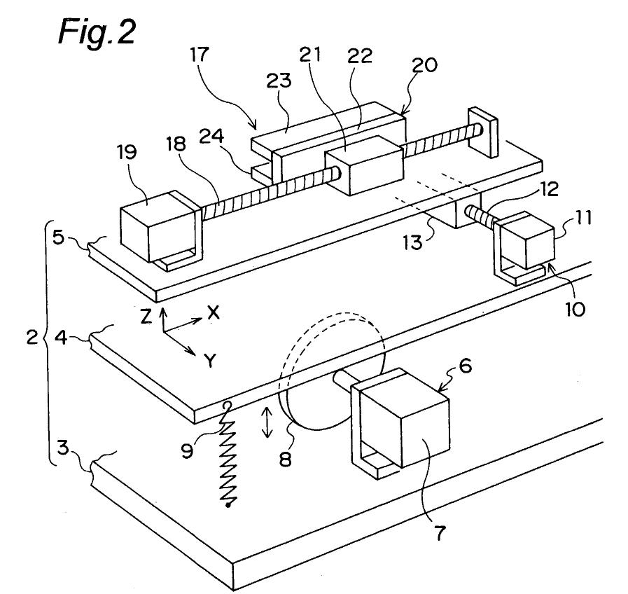

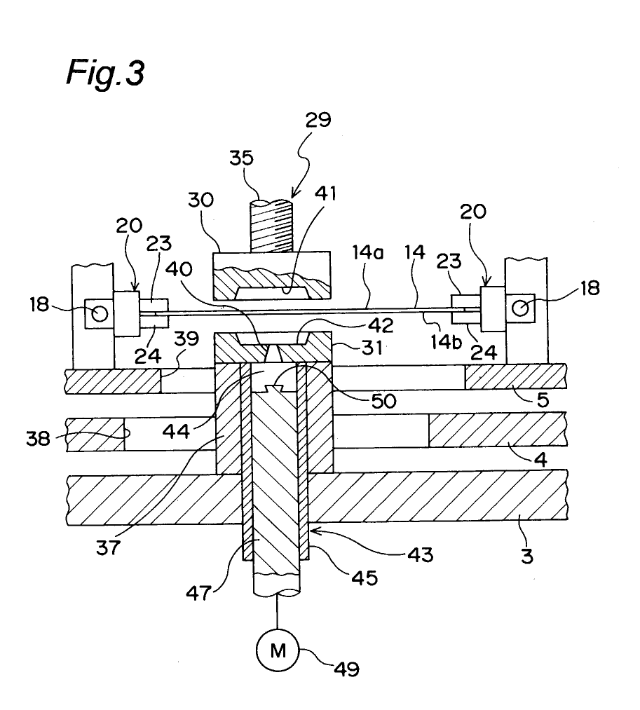

FIG. 1 illustrates the resin molding apparatus according to the first embodiment of the present invention. The resin molding apparatus 1 includes a platform 2 for supporting various other components as described hereinafter. As clearly shown in FIGS. 2 and 3, the platform 2 has a first table (fixed table) 3 fixed to an anchored member (not shown) such as a floor. It also has a second table (elevating table) 4 supported on the first table 3 capable of elevating in a vertical direction (Z-direction). Further, the platform 2 has a third table (shifting table) 5 supported on the second table 4 capable of shifting in a lateral direction (Y-direction).

The resin molding apparatus 1 includes an elevating member or mechanism 6 for elevating the second table 4 in the vertical direction relative to the first table 3 as shown in FIG. 2. The elevating mechanism 6 has, for example, a plurality of first motors 7, each of which is equipped with an eccentric cam 8 arranged around a rotating shaft thereof. The second table 4 is designed so that it is maintained to be even while it elevates in the vertical direction in accordance with the operation of the first motors 7 and hence the eccentric cams 8. Preferably, a plurality of springs 9 connected between the first and second tables 3, 4 are provided for biasing the second table 4 downwardly towards the first table 3.

The resin molding apparatus 1 also includes a lateral shifting member or mechanism 10 for shifting the third table 5 in the lateral direction (Y-direction) relative to the second table 4. The lateral shifting mechanism 10 has a second motor 11 mounted on the second table 4, a ball screw 12 extending in the Y-direction that is drivably connected to the second motor 11, and a nut member 13 that is fixed to the third table 5 and threaded with the ball screw 12. The lateral shifting mechanism 10 may have a plurality of second motors 11, ball screws 12, and nut members 13, each of them cooperating together with others. The rotation of the second motor 11 and the ball screw 12 connected thereto cause a reciprocation shift of the nut member 13 and the third table 5 fixed thereto in the Y-direction.

(2) Magazines

Referring back to FIG. 1, a first and second magazines (containers) 15, 16 are arranged at both sides along the X-direction perpendicular to the Y-direction, for receiving a plurality of the lead frames 14. Thus, the first and second magazines 15, 16 opposes to each other and the platform 2 is positioned between the magazines 15, 16. Each of the lead frames 14 has an upper and lower surfaces (first and second principal surfaces) 14a, 14b, respectively. One or more uncovered (pre-molded) elements 28 such as exposed semiconductor chips are mounted on at least one of the upper and lower surfaces 14a, 14b, and are to be molded with resin by the resin molding apparatus 1. Thus, a plurality of the lead frames 14 with the uncovered and covered elements 28 are stacked in the first and second magazines 15, 16, respectively.

(3) Frame Transporting Mechanism

The lead frames 14 are transported along a transporting path from the first magazine 15 to the second magazine 16 by a pair of frame transporting mechanisms 17 provided on both sides of the transporting path. (For clarification, only one frame transporting mechanism 17 is illustrated in FIGS. 1 and 2.) Each of the lead frame transporting mechanisms 17 has a ball screw 18 extending from the first magazine 15 to the second magazine 16 in the X-direction. The ball screw 18 is drivably connected to a third motor 19 fixed on the third table 5 so as to rotate a longitudinal shaft thereof.

As shown in FIG. 2, each of the ball screws 18 includes a chuck member (holder or holding member) 20 for holding a side-edge portion of the lead frame 14 extending in the X-direction. The chuck member 20 has a movable nut 21 threaded with the ball screw 18 so that it can be translated in the X-direction in accordance with the rotation of the third motor 19. The chuck member 20 also has a vertical plate 22 secured to the movable nut 21, and an upper and lower holding plates 23, 24 connected to the vertical plate 22. The upper and lower holding plates 23, 24 can be moved in a vertical direction by an activating mechanism (not shown) so as to hold the side-edge portion of the lead frame 14. The activating mechanism may have a driving mechanism (not shown) such as a motor and a solenoid. Alternatively, the activating mechanism may have a spring and a releasing mechanism (not shown), in which the upper and lower holding plates 23, 24 are biased to each other by the spring, and separated by the releasing mechanism so as to release the lead frame held between the holding plates 23, 24. In the latter case, preferably, a pair of the releasing mechanisms are arranged adjacent to the first and second magazines 15, 16.

(4) Actuator

Again, referring to FIG. 1, the resin molding apparatus further includes a first and second actuators 25, 26. The first actuator 25 is designed to move in accordance with a driver such as a motor (not shown) between an approaching position adjacent to the first magazine 15 and a separating position spaced from the approaching position by a predetermined distance along the X-direction. The first actuator 25 picks the lead frame 14 at the approaching position and draws it from the first magazine 15 to slide it to the separating position on the chunk members 20 located at a first position P1. When the lead frame 14 fully rides on the chunk members 20 positioned at the first position P1, the chunk members 20 holds the lead frame 14.

As above, the chuck members 20 can be translated in the X-direction while the lead frame 14 is supported by the chuck members 20, and later on, the lead frame 14 is released by the chunk members 20 located at a third position P3.

Meanwhile, the second actuator 25 is designed to move in accordance with a driver such as a motor (not shown) between another approaching position adjacent to the second magazine 16 and another separating position spaced from the approaching position by a predetermined distance along the X-direction. The second actuator 26 urges and slides the lead frame 14 on the chunk member 20 located at the third position P3 so as to deliver it into the second magazine 16.

(5) Molding Dice

The resin molding apparatus includes a molding mechanism 29 secured to the first table 3 of the platform 2 at a second position P2 between the first and third positions P1, P3. The molding mechanism 29 molds the elements mounted on the lead frame 14 with resin by an individual package at one time. Also, the molding mechanism 29 includes an upper and lower molding dice 30, 31 covering elements on the upper and lower surfaces of the lead frame 14, respectively, as shown in FIG. 3.

As illustrated in FIG. 1, the upper molding die 30 is equipped with an upper-die elevating unit 32 so that it can be moved vertically in a Z-direction. The upper-die elevating unit 32 includes a pair of columns 33 arranged on both side of the transporting path and secured on the first table 3, and a lateral supporting frame 34 connected between the columns 33. The upper-die elevating unit 32 also includes a vertical shaft 35 movably supported by the lateral supporting frame 34 and connected to the upper molding die 30 at the bottom. The vertical shaft 35 is driven vertically by a fourth motor 36 so that the upper molding die 30 connected to the vertical shaft 35 is elevated in accordance with the rotation of the fourth motor 36.

On the other hand, the lower molding die 31 is supported on a cylindrical supporting seat 37 secured on the first table 3. The second and third tables has openings 38, 39, respectively, allowing the lateral shift and the vertical movement thereof without interfering the lower molding die 31 and the supporting seat 37.

As shown in FIG. 3, the lower molding die 31 has at least one resin injecting hole (gate) 40 provided in the center region thereof, extending vertically through the lower molding-die 31. Preferably, the lower molding die 31 has a tapered tip towards the upper end thereof.

(6) Resin Injecting Mechanism

A resin injecting mechanism (injector) 43 is arranged within the cylindrical supporting seat 43 for injecting resin through the resin injecting hole 40 into the cavities 41, 42 defined within the upper and lower molding dice 30, 31. The resin injecting mechanism 43 has a cylinder 45 defining a space (chamber) 44 in fluid communication with the resin injecting hole 40. The cylinder 45 extends downwardly through the first table 3 to a resin tablet loading mechanism as described below. The cylinder 45 is equipped with a heater (not shown) provided at any appropriate positions so as to perform a function of heating to melt the resin tablets within the cylinder 45.

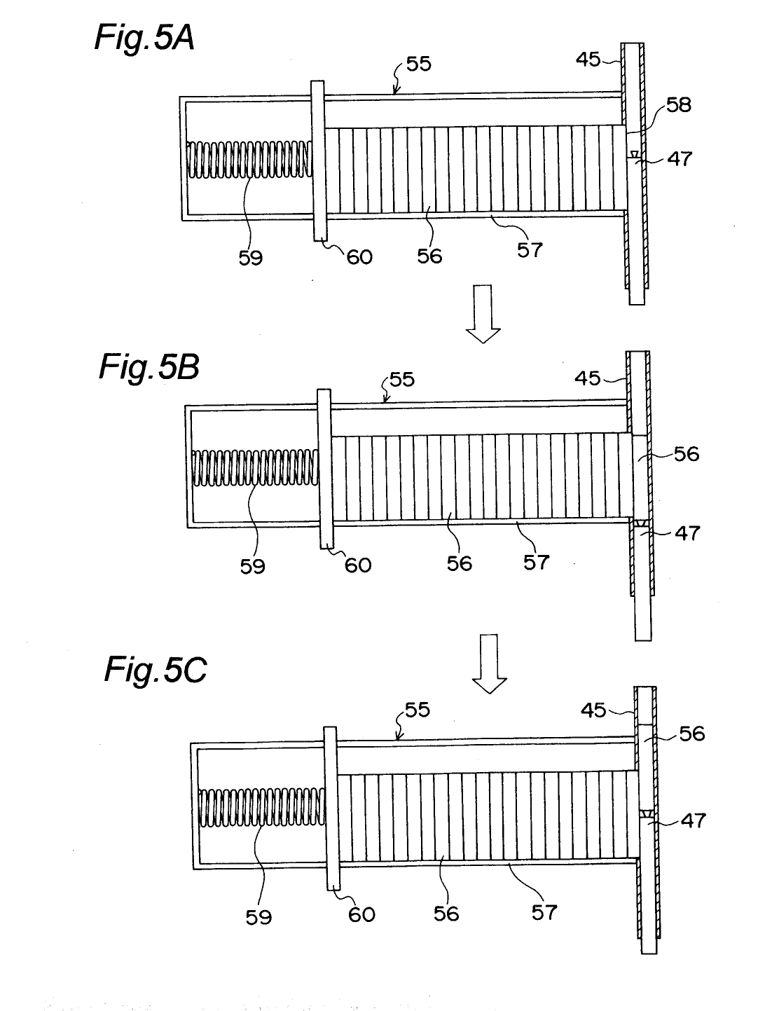

Provided within the cylinder 45 is a rod-like plunger 47 having the outer diameter substantially the same as the inner diameter of the cylinder 45. The plunger 47 is drivably connected to any suitable driving mechanism 49 such as a motor so that it is elevated in the vertical direction by the driving mechanism 49 between the uppermost position shown in FIG. 3 and the lowermost position illustrated in FIG. 5B.

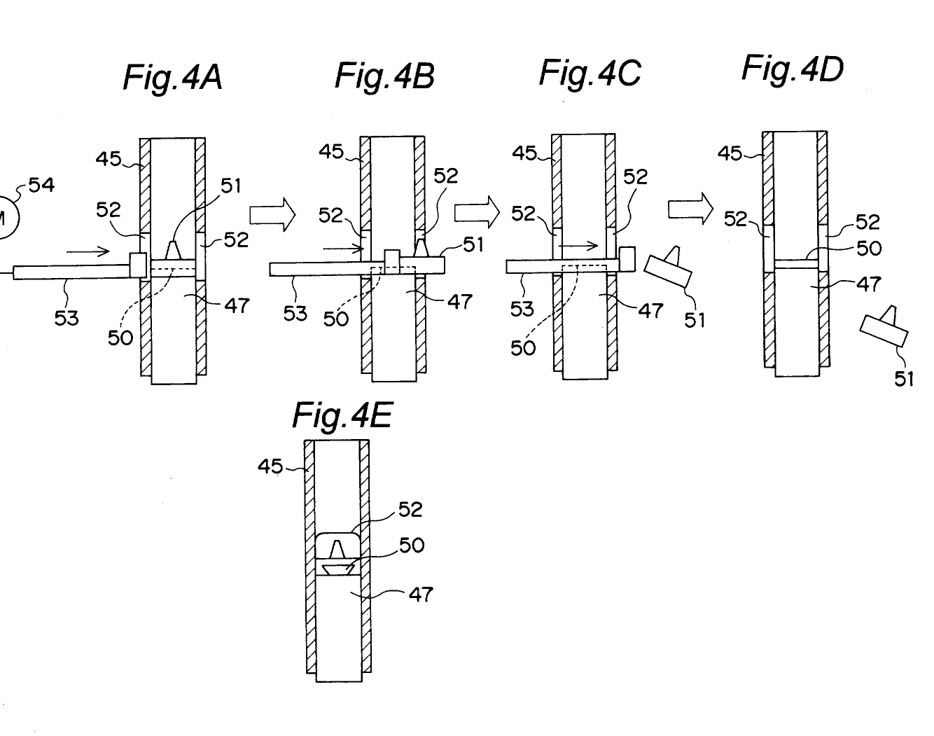

The plunger 47 has an engaging lug 50 integratedly formed on an upper surface of the plunger 47. The engaging lug 50 has a rail-like configuration extending in a direction perpendicular to the center axis of the cylinder 45 as shown in one cross sectional views of FIGS. 4A to 4D taken along the X-Z plane of FIG. 1. Also, in FIG. 3 showing another cross sectional view taken along the Y-Z plane of FIG. 1, the engaging lug 50 has a width greatest at the top portion and gradually decreasing towards the bottom portion thereof (upper end surface of the plunger 47). Thus, the lug 50 is configured to be like a rail with the cross section of a reverse trapezoid extending in the Y-direction between the outer surfaces of the plunger 47. This configuration secures the engagement with the cured resin (cull) 45 remaining in the chamber 44 and facilitates the removal thereof, as described below, by pulling the plunger 47 downwardly.

(7) Cull Removing Mechanism

The cylinder 45 has a pair of through holes or openings 52 at the middle portion extending in the longitudinal direction of the engaging lug 50. The cull removing mechanism has a cull ejecting bar (ejector or ejecting member) 53 that can be moved back and forth by a driving mechanism 54 via the openings 52 without interfering with the engaging lug 50. When the cull ejecting bar 53 moves to urge the cull 51, sliding the engaged cull 51 on the rail-like lug 50 for the ejection. Also, it should be noted that although not illustrated in the drawings, the engaging lug 50 may be designed to have the size of the cross section reducing towards the longitudinal sliding direction (left to right direction in FIGS. 4A to 4D) in order to further facilitate the removal of the cull 51 from the plunger 47.

(8) Resin Tablet Loading Mechanism

As shown in FIGS. 5A, 5B, and 5C, a resin tablet loading mechanism (resin loader) 55 is provided adjacent to the bottom end of the cylinder 45. The resin tablet loading mechanism 55 has a housing (container) 57 for receiving a plurality of stick-like tablets 56 directing vertically and being arranged in parallel in the lateral direction. The housing 57 has one lateral end in communication with a tablet inserting hole (opening) 58 provided on the side surface of the cylinder 45 so that the tablet 56 received within the housing 57 can be loaded into the cylinder 45 via the tablet inserting hole 58.

To facilitate the loading of the tablet 56 into the cylinder 45, the housing 57 has a spring (biasing member or loading member) 59 provided on the other lateral end opposite to the cylinder 45, and a pushing plate 60 for pushing the tablets 56 towards the tablet inserting hole 58. When the plunger 47 locates adjacent to the tablet inserting hole 58 as shown in FIG. 5A, the loading of the tablet 56 is disturbed. When the plunger 47 is retracted below the tablet inserting hole 58 as shown in FIG. 5B, the tablet 56 is pushed by the biasing force of the spring 59 and loaded into the cylinder 56. Then, the tablet loaded into the cylinder 45 is lifted with the plunger 47 moving upwardly, and during the lifting, it is heated by the heater equipped with the cylinder 45 and melted within the cylinder 45 to obtain the melted resin. As above, the melted resin is injected via the injecting hole 40 into the upper and lower cavities 41, 42 of the upper and lower molding dice 30, 31.

II. Operation of Resin Molding Apparatus

Next, the operation of the resin molding apparatus 1 of the present invention will be described hereinafter. Referring to FIG. 1, a plurality of the lead frames 14 with the pre-molded elements such as exposed semiconductor chips mounted thereon are kept in the first magazine 15. One of the lead frames 14 is picked up and drawn by the first actuator 26 and set at the first position P1. Thus, while the upper and lower holding plates 23, 24 is kept in a releasing position shown in FIG. 2, the lead frame 14 is guided into a gap between the upper and lower holding plates 23, 24 of the pair of the chuck members 20 of the lead frame transporting mechanisms 17. Once the lead frame 14 is fully drawn by the first actuator 25, the pair of the upper and lower holding plates 23, 24 are driven to hold the side surfaces of the lead frame 14 in the gap as shown in FIG. 3.

The rotation of the ball screw 18 driven by the third motor 19 transports the chuck member 20 with the lead frame 14 to the molding mechanism 29 arranged at a second position P2. To this end, one of the elements to be firstly molded is aligned in the vertical direction between the upper and lower molding dice 30, 31. If the lead frame needs to be aligned also in the Y-direction as well, the second motor 11 is driven to shift the third table 5 in the direction perpendicular to the transporting direction of the lead frame.

Once the vertical alignment of the lead frame 14 relative to the molding dice 30, 31 is completed, the first motor 7 is driven to lower the second and third tables 4, 5 until the lead frame 14 adjoins the lower molding die 31. Then, the fourth motor 36 is driven to lower the upper molding die 30 until it contacts with the lead frame 14. This causes the cavities 41, 42 to define a molding cavity between the upper and lower molding dice 30, 31, which covers and surrounds the element 28 mounted on the lead frame 14. Next, the resin is injected from the resin injecting mechanism 43 via the resin injecting hole 40 to the cavity 42 of the lower molding die 31. It should be noted that the lead frame 14 has one or more openings within the molding cavity allowing the fluid resin to run from the lower cavity 42 into the upper cavity 41 via the openings.

After completing to mold one of the elements 28 with resin, the fourth motor 36 of the upper-die elevating unit 32 is driven to lift the upper molding die 30, thereby separating thereof from the molded resin. Since the chuck member 20 holds the lead frame 14, the molded resin can easily be separated from the upper molding die 30. The first motor 7 is driven to lift the second and third tables 4, 5 relative to the first table 3 in order to separate the lower molding die 31 from the molded resin, while the chuck member 20 holds the lead frame 14.

Then, if desired, the second motor 11 is driven to shift the third table 5 and hence the lead frame 14 in the Y-direction. Also, if required, the third motor 19 is driven to transport the second table 4 and hence the lead frame 14 in the X-direction. Such shift and transport align the element to be subsequently molded in the position between and relative to the upper and lower molding dice 30, 31.

Once the elements mounted on the lead frame 14 are all molded as above, the chuck member 20 with the lead frame 14 is transported to the third position P3. Then, the upper and lower holding plates 23, 24 of the chuck member 20 release the lead frame 14. The released lead frame 14 are urged by the second actuator 26, and delivered into the second magazine 16. Again, the other lead frames 14 kept in the first magazine 15 are repeatedly processed to mold the elements with resin.

The resin tablet loading mechanism 55 supplies resin material necessary for molding the elements 28. As shown in FIG. 5, when the plunger 47 retracts downwardly beyond the tablet inserting hole 58, the resin tablet 56 is pushed by the biasing force of the spring 59 and loaded into the cylinder 56 (FIG. 5B). Then, the resin tablet 56 loaded into the cylinder 45 is lifted with the plunger 47 moving upwardly. During the lifting, the resin tablet 56 is heated by the heater equipped with the cylinder 45 and melted within the cylinder 45 to obtain the melted resin. As above, the melted resin is injected via the injecting hole 40 into the upper and lower cavities 41, 42 of the upper and lower molding dice 30, 31.

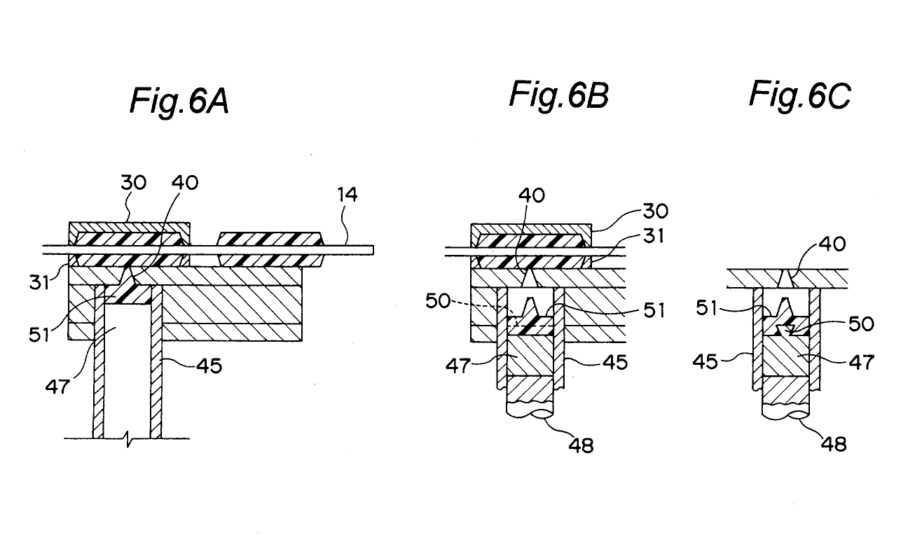

As illustrated in FIGS. 3 and 6A, the uppermost position of the plunger 47 is determined so that the chamber 44 has a height greater than that of the engaging lug 50. Therefore, a part of the melted resin is remained and cured within the chamber 44 and the resin injecting hole 40 to form the cull 51. The cull 51 so formed encompasses the rail-like engaging lug 50 having the cross section of the reverse trapezoid. Therefore, when the plunger 47 retracts downwardly for introducing another resin tablet into the cylinder 45, the cull 51 is also pulled down and separated from the molded resin within the lower cavity 42 at the uppermost end of the resin injecting hole 40, which has the smallest abutting area between the molded resin and the cull 51.

While the cull 51 engaged with the plunger 47 is moving adjacent to the openings 52 in the cylinder 45, as shown in FIGS. 4A to 4E, the cull ejecting bar 53 urges and slides the cull 51 on the rail-like lug 50 for ejecting it outside the cylinder 45.

As described above, the lead frame 14 has a plurality of elements 28 mounted thereon, each of which is individually molded according to the present embodiment, therefore, the resin molding apparatus can be reduced in size. This reduces the space (area) in the facility required for installing the apparatus and improves the efficiency of energy required for running the resin molding apparatus. Also, the structure of the resin molding apparatus 1 can be simplified so that the cost of the apparatus is reduced. Further, the contacting surfaces of the upper and lower molding dice 30, 31 can be reduced, so that the contacting surface across the upper and lower molding dice 30, 31 has the even pressure and temperature independent on the position of the molding dice. Even further, each of the elements is molded separately, the molding step can be controlled and monitored in an efficient manner.

According to the resin molding apparatus 1 of the present embodiment, a plurality of elements 28 mounted on the lead frame 14 are subsequently molded with resin by shifting the chunk member 20 relative to the molding dice 30, 31. Therefore, the resin molding apparatus 1 having the mechanisms for shifting the chunk member 20 can be reduced in weight, in comparison with the other types of apparatuses having a mechanism for shifting the heavy molding dice. To this end, the space (area) required for installing the apparatus in the facility can be reduced, the efficiency of energy required for running the resin molding apparatus can be improved.

In addition, in the resin molding apparatus 1, since the chuck member 20 holding the lead frame 14 at the first position P1 is transported to the third position P3 via the second position P2 where the element 28 is molded with resin. Thus, the chuck member 20 grabs and releases the lead frame 14 only one time for each molding step, which substantially reduces the possibility to fail grabbing the lead frame 14 (i.e., jam troubles). Therefore, time and effort to recover the jam troubles can be substantially reduced so that the productivity or the efficiency of the production are remarkably improved according to the present embodiment.

Also, according to the present embodiment, the elevation of the chuck member 20 with the lead frame 14 relative to the molding dice 30, 31 causes the molded resin and the molding dice 30, 31 to be separated to each other. Therefore, an another ejecting mechanism can be eliminated for ejecting the molded resin from the molding dice 30, 31. This reduces the producing cost of the molding dice. Such an ejecting mechanism would have a plurality of boosting members such as pins pushing up the molded resin in the molding dice, then the stress would be focused on the portion of the molded resin pushed by the pins. To this end, this could cause any adverse effects to the molded resin and the electrical elements embedded therein. However, according to the present invention, such adverse effects can be excluded.

In the resin molding apparatus 1 described above, the resin is injected into the cavity 42 from the resin injecting hole 40 arranged on the bottom surface of the lower molding die 31. Therefore, the formation of the resin burr at the contacting surfaces of the molding dice can be reduced in comparison with that of the conventional resin molding apparatus having the resin injecting hole (gate) arranged between the contacting surfaces of the molding dice. Thus, the resin burr flying around the molding dice can also be reduced so that time and task to remove the resin burr can substantially be reduced.

Also, when the plunger 47 passes by the tablet inserting hole (opening) 58 to load the resin tablet 56 into the cylinder 45, since the plunger 47 of the present embodiment has the outer diameter substantially the same as the inner diameter of the cylinder 45, the plunger 47 and the resin tablet 56 hardly interfere to each other. This eliminates or substantially reduces the possibility of damage of the resin tablet 56 caused by the plunger 47 hitting thereto.

The resin molding apparatus 1 requires no runner portion, which, in the conventional resin molding apparatus, could be provided between the chamber of the cylinder for receiving the melted resin and the cavity of the molding die. Thus, according to the present embodiment, the resin material is utilized in an efficient manner without wasting to form the undesired resin at the runner portion.

The resin injecting hole 40 is configured to have a tapered tip towards the upper end thereof, at which the molded resin within the molding dice 30, 31 is separated from the remaining resin material within the chamber 44. Therefore, after the molding step, the necessity of a gate formation mechanism for aligning the molded resin with and separating thereof from any undesired resin, which is otherwise required in the conventional resin molding apparatus, is eliminated. This can simplify the structure of the resin molding apparatus, thereby: reducing its cost and occupying space (area) in the facility.

Further, the gate formation (i.e., the separation between the molded resin and the redundant resin) before the complete curing thereof causes no crack in the molded resin, thereby to reduce the possibility of the defective products and improve the reliability and the productivity.

In the resin molding apparatus 1 of the present embodiment, the cull 51 remaining on the engaging lug 50 in the chamber 44 and can easily be ejected by retracting the plunger 47 downwardly. Therefore, a complicated structure of the molding dice having a plurality of separated blocks only for ejecting the cull as the prior art resin molding apparatus can be eliminated. Also, the engaging lug 50 with the cross section of the reverse trapezoid secures engaging with the cull 51 and brings it downwardly for the ejection without the jam troubles. The cull ejecting bar 53 secures the ejection of the cull 51 from the tip of the plunger 47.

Embodiment 2.

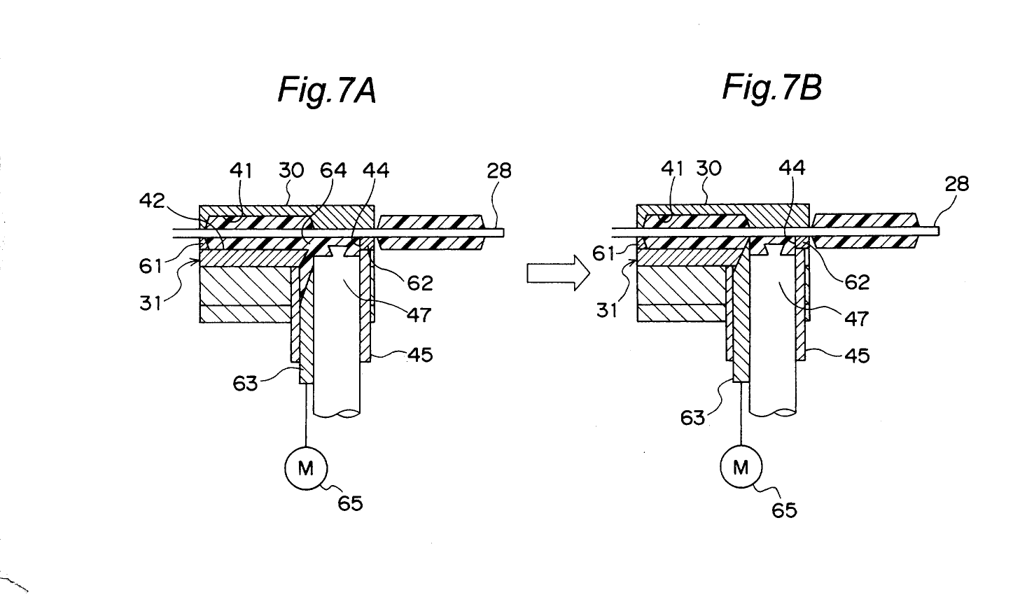

Referring to FIGS. 7A and 7B, the second embodiment of the resin molding apparatus according to the present invention will be described hereinafter. Since the resin molding apparatus of the second embodiment has a structure similar to that of embodiment 1 except that the lower molding die has three individual molding members. Therefore, any duplicated description will be eliminated focusing on the lower molding die.

As above and illustrated in FIGS. 7A and 7B, the lower molding die 31 includes a first, second, and third molding members 61, 62, 63. As shown, the first molding member 61 defines the most of the outline of the cavity 42. The second molding member 62 defines the most of the outline of the chamber 44 for receiving the remaining resin (cull) within the cylinder 45. The first and second molding members 61, 62 are in a fluid communication with each other via a resin injecting hole 64. The third molding member 63 is drivably connected to a driving mechanism such as a motor so that it can be moved between the upper position (close position) shown in FIG. 7A and the lower position (open position) shown in FIG. 7B. The lower position of the third molding member 63 causes the first and second molding members 61, 62 in fluid communication with each other. On the other hand, the third molding member 63 in the upper position (close position) defines the cavity 42 entirely in cooperation with the first molding member. 61, and as well as the chamber 44 completely in cooperation with the second molding member 62 by interrupting the resin injecting hole 64 (the fluid communication between the first and second molding members 61, 62).

Thus, during injecting the resin into the cavity 42, the third molding member 63 retracts in the lower position to connect the first and second molding members 61, 62, and the plunger 47 is pushed up to guide the resin from the chamber 44 into the cavity 42. Then, the third molding member 63 is lifted from the lower position to the upper position to define the cavity 42 and the chamber 44. To this end, the molded resin (injected resin) within the cavity 42 is separated from the remaining or redundant resin (cull) in the chamber 44.

In the resin molding apparatus so constructed, the limited amount of the undesired resin to be ejected remains on the upper surface of the plunger 47, thus resin material can be utilized in an efficient manner. Also, the molded resin has no unnecessary portion positioned corresponding to the runner portion, no mechanism is required for removing the redundant resin.

In the aforementioned description, the elements 28 mounted on both surfaces of the lead frame 14 are molded by filling up the upper and lower cavities with resin. However, it should be noted that, in case where the lead frame 14 has the elements mounted on only one surface thereof, either one of the upper and lower molding dice 30, 31 may have the cavity covering the element on the lead frame 14.

Also, in the above-mentioned description, the engaging lug 50 is formed so as to hold the cull 51 on the upper surface of the plunger 47. Alternatively, a groove or channel may be formed on the upper surface of the plunger 47 having the cross section of a trapezoid with a width greatest at the bottom portion and gradually decreasing towards the top portion thereof (upper end surface of the plunger 47).

What is claimed is:

1. A resin molding apparatus, comprising:
a holder for controllably holding and releasing a lead frame having a first and second principal surfaces and a plurality of elements mounted on at least one of the first and second principal surfaces;
a transporter for transporting said holder with the lead frame from a first position via a second position to a third position;
a first and second molding dice controllably adjoining the first and second principal surfaces of the lead frame arranged on the second position, respectively, so that a molding cavity is defined therebetween, which covers the element of the lead frame;
a resin injector for injecting resin into the molding cavity; and
an elevator for elevating said holder with the lead frame arranged on the second position in a direction perpendicular to the first and second principal surfaces.

2. The resin molding apparatus according to claim 1, further comprising:
a first container for receiving a plurality of the lead frames;
a first actuator for drawing one of the lead frames from said first container to said holder;
a second actuator for delivering the lead frame released by said holder into a predetermined position.

3. The resin molding apparatus according to claim 1, further comprising:
an injector having a chamber in fluid communication with the molding cavity via a through hole;
wherein the through hole has a tapered tip towards the molding cavity.

4. The resin molding apparatus according to claim 1,
wherein one of the molding dice further including,
a first molding member defining the most of the outline of the molding cavity,
a second molding member defining the most of the outline of the chamber, and
a third molding member capable of moving between an open and close positions,
wherein the third molding member in the open position allows fluid communication between the molding cavity and the chamber, and the third molding member in the close position interrupts the fluid communication therebetween, and
wherein the third molding member in the close position defines the cavity entirely in cooperation with the first molding member, and as well as the chamber completely in cooperation with the first molding member.

5. A resin molding apparatus, comprising:
a holder for controllably holding and releasing a lead frame having a first and second principal surfaces and a plurality of elements mounted on at least one of the first and second principal surfaces;
a pair of molding mechanisms controllably adjoining the first and second principal surfaces of the lead frame, so that the element of the lead frame is covered within a molding cavity and molded with resin; and
an elevating mechanism for elevating said holder with the lead frame in a direction perpendicular to the first and second principal surfaces.

6. The resin molding apparatus according to claim 5, further comprising:
a first container for receiving a plurality of the lead frames;
a first actuator for drawing one of the lead frames from said first container to said holder;
a second actuator for delivering the lead frame released by said holder into a predetermined position.

7. The resin molding apparatus according to claim 5, further comprising:
an injector having a chamber in fluid communication with the molding cavity via a through hole;
wherein the through hole has a tapered tip towards the molding cavity.

8. The resin molding apparatus according to claim 5,
wherein one of the molding mechanism further including,
a first molding member defining the most of the outline of the molding cavity,
a second molding member defining the most of the outline of a chamber, and
a third molding member capable of moving between an open and close positions,
wherein the third molding member in the open position allows fluid communication between the molding cavity and the chamber, and the third molding member in the close position interrupts the fluid communication therebetween, and
wherein the third molding member in the close position defines the cavity entirely in cooperation with the first molding member, and as well as the chamber completely in cooperation with the first molding member.

9. A resin molding apparatus, comprising:
a molding die including a molding cavity covering an element mounted on a lead frame, and a chamber connected to the molding cavity, the molding cavity being filled up with melted resin injected from the chamber;
a loader for loading a resin tablet into the chamber;
a heater for heating a resin tablet within the chamber to prepare melted resin; and
an injector for injecting the melted resin into the molding cavity.

10. The resin molding apparatus according to claim 9,
wherein the melted resin remains in the chamber to form a cured resin; and
wherein said injector has an engaging member facing to the chamber, for engaging with the cured resin in the chamber.

11. The resin molding apparatus according to claim 10,
wherein said injector moves in an injecting direction to inject the melted resin into the molding cavity; and
wherein the engaging member has a lug extending in an extending direction perpendicular to the injecting direction and having a width in a direction perpendicular to the extending and injecting directions, the width increasing towards the injecting direction.

12. The resin molding apparatus according to claim 10,
wherein said injector moves in an injecting direction to inject the melted resin into the molding cavity; and
wherein the engaging member is a groove extending in an extending direction perpendicular to the injecting direction and having a width in a direction perpendicular to the extending and injecting directions, the width decreasing towards the injecting direction.

13. The resin molding apparatus according to claim 11, further comprising:
an ejector for ejecting the cured resin engaged with the engaging member.

14. The resin molding apparatus according to claim 12, further comprising:
an ejector for ejecting the cured resin engaged with the engaging member.
